(19) United States
(12) Patent Application Publication
(10) Pub. No.: US 2014/0106550 A1
(43) Pub. Date: Apr. 17, 2014

(54) ION IMPLANTATION TUNING TO ACHIEVE SIMULTANEOUS MULTIPLE IMPLANT ENERGIES

(71) Applicant: INTERNATIONAL BUSINESS MACHINES CORP, Armonk, NY (US)

(72) Inventors: Anthony I. Chou, Beacon, NY (US); Murshed M. Chowdhury, Newburgh, NY (US); Arvind Kumar, Beacon, NY (US); Shreesh Narasimha, Beacon, NY (US); Craig M. Sinn, Wappingers Falls, NY (US)

(73) Assignee: INTERNATIONAL BUSINESS MACHINES CORPORATION, Armonk, NY (US)

(21) Appl. No.: 13/649,364

(22) Filed: Oct. 11, 2012

(51) Int. Cl. H01L 21/265

(52) U.S. Cl. 438/527; 257/E21.334

(57) ABSTRACT

A method of ion implantation is disclosed. A beam of ions is accelerated to a first energy level. The beam of ions is decelerated from the first energy level to produce a contamination beam of ions via an ion collision process. The ions of the contamination beam are implanted in a substrate to obtain a selected dopant profile in the substrate.

### BACKGROUND

The present invention relates generally to ion implantation and in particular to a method for achieving a desired ion dopant profile.

Ion implantation is a common ion doping method used in the semiconductor industry. In ion implantation, ions are stripped from an ion source and brought to a selected energy level suitable for implantation in a substrate. Generally, ions are accelerated from the ion source to a first (high) energy level. The ions are then decelerated to a second (low) energy level, wherein the ions are implanted at the second energy level. The energy of the ions upon impact with the substrate determines a penetration depth of the ions and a subsequent dopant profile. During the deceleration process, a contamination beam of ions is often produced consisting of ions that are neutralized via atomic collisions. These neutralized ions are considered undesirable and are generally removed from the ion beam to provide a “clean” ion beam impacting the substrate at the second energy level. The clean ions are then implanted in the substrate. While the clean ions generally produce a known dopant profile in the substrate, dopant profiles other than that which can be achieved using clean ion beams are generally desired. In order to achieve these different dopant profiles, two or more implantation steps are generally used.

### SUMMARY

According to one embodiment, a method of ion implantation includes: accelerating a beam of ions to a first energy level; decelerating the beam of ions from the first energy level to produce a contamination beam of ions via an ion collision process; and implanting ions of the contamination beam in a substrate to obtain a selected dopant profile in the substrate.

According to another embodiment, a method of obtaining an ion doping profile includes: accelerating a beam of ions to a first energy level; decelerating the beam of ions from the first energy level to produce a contamination beam of ions; and implanting ions of the contamination beam in a substrate to obtain at least a first portion of the ion doping profile.

According to another embodiment, a method of doping a substrate includes: decelerating an ion beam from a first energy level to a second energy level to produce a contamination ion beam; and directing the contamination ion beam onto the substrate to dope the substrate.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 shows an exemplary ion implantation apparatus suitable for performing the ion implantation methods disclosed herein;

FIG. 2 shows a graph of energy state of an exemplary ion beam at various locations in the ion implantation apparatus of FIG. 1;

FIG. 3 shows an exemplary dopant profile that may be obtained in a substrate from an ion beam produced using the exemplary ion implantation apparatus of FIG. 1;

FIG. 4 shows various dopant profiles obtained using the methods disclosed herein;

FIG. 5 shows a flowchart illustrating an exemplary method of obtaining a selected dopant profile in a substrate;

FIG. 6 shows an exemplary semiconductor device formed using the methods disclosed herein;

FIG. 7 shows an exemplary wafer substrate having an existing structure formed on its surface; and

FIG. 8 shows an exemplary ion implantation apparatus suitable for performing the ion implantation of multiple ion species.

### DETAILED DESCRIPTION

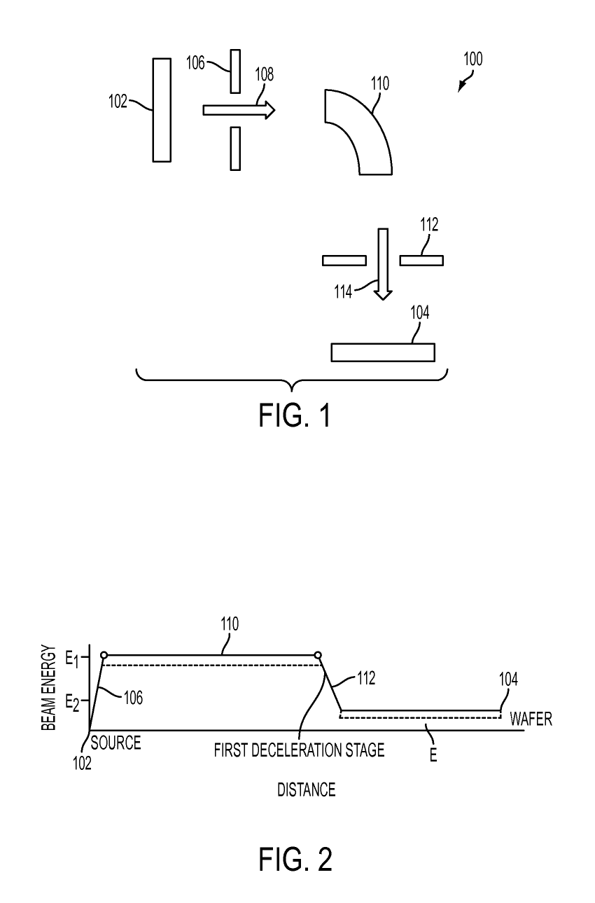

FIG. 1 shows an exemplary ion implantation apparatus 100 suitable for performing the ion implantation methods disclosed herein. An ion source 102 provides ions at a front end of the apparatus 100 and a substrate 104 or other suitable material is provided for receiving the ions at a back end of the apparatus 100. An acceleration electrode 106 extracts a beam of ions from the ion source 102 and accelerates the ions to a first energy level. The acceleration electrode 106 generally operates based on interaction between electromagnetic fields and the ionic charge. In general, the first energy level is selected to enable throughput in the ion implantation apparatus and is therefore higher than an energy at which the ions are implanted into the substrate 104. The accelerated beam 108 passes through a beam line 110, after which a decelerating electrode 112 reduces the energy of the ion beam from the first energy level to a second energy level. The deceleration electrode 112 activates an electromagnetic field to interact with the charged ions to decelerate the ions. The second energy level generally corresponds to a selected implantation energy of the ions. The ion beam 114 exiting the deceleration lens 112 is then directed towards the substrate 104, wherein the ions of the ion beam 114 are implanted in the substrate 104, typically as dopants to the substrate.

FIG. 2 shows a graph of energy state of an exemplary ion beam at various locations in the ion implantation apparatus 100 of FIG. 1. Beam energy is shown along the y-axis and distance along the beam path is shown along the x-axis. Ions are pulled from the ion source at 102 and are accelerated at the acceleration electrode 104 to the first energy level, denoted as E₁. The ion beam traverses the beam line 110 while at the first energy level and is thereafter decelerated to second energy level at decelerating electrode 112. The second energy level is denoted as E₂. The ion beam exits the decelerating electrode at the second energy level and thus impacts the substrate 104 at the second energy level. In various embodiments, the ions at the second energy level may be further decelerated to a third energy level using another deceleration electrode.

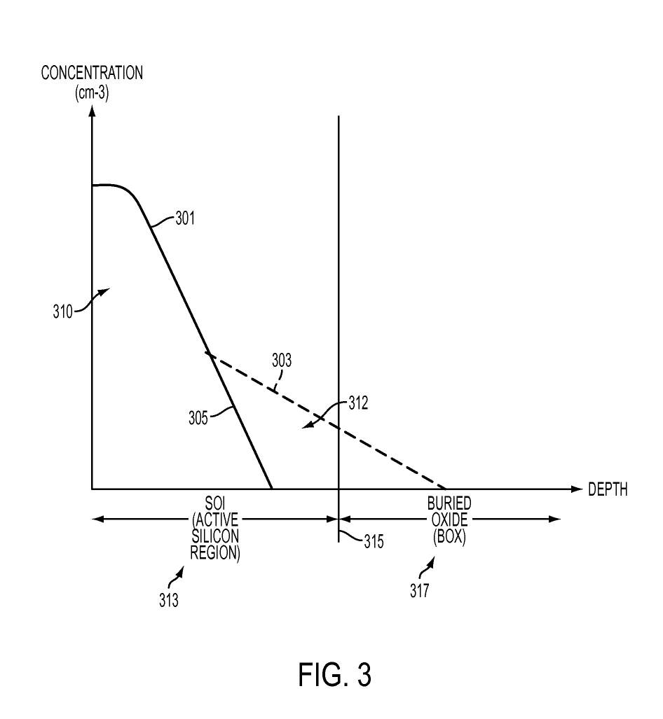

In general, some ions traversing the exemplary ion implantation apparatus 100 experience an energy contamination interaction, wherein the ions may collide with atoms and/or molecules of residual gases in the path of the ion beam. During the collision, charge may be exchanged between the ions and the residual gases, thereby neutralizing the ions. As a result of this interaction, ion beam 114 impinging on a substrate generally includes a “clean” beam includes neutralized ions that have not experienced ion exchange and a “contamination” beam containing ions that have experienced ion exchange. Most ions are included in the clean beam, while a relatively small proportion of the ions become neutralized ions and are included in the contamination beam. The energy level of the clean beam may be controlled using the deceleration electrode 112 and thus the clean ions may be injected into the substrate at a selected energy level. The neutralized ions are unaffected by the deceleration electrode 112, and thus the contamination beam is not decelerated to the second energy level. Therefore, neutralized ions are injected into the substrate at an energy different from (higher than) the second energy level. The results of these different implantation energies are shown with respect to FIG. 3.

FIG. 3 shows an exemplary dopant profile 300 that may be obtained in a substrate from an ion beam produced using the exemplary ion implantation apparatus 100 of FIG. 1. The exemplary dopant profile includes a shallow dopant profile 301 resulting from the implantation of clean ions and a deep dopant profile 303 resulting form the implantation of the neutralized ions, also referred to herein as contamination ions. The shallow dopant profile 301 is a result of the relatively high concentration of ions in the clean beam that impact the substrate at a relatively low energy, i.e., the second energy level. Thus, shallow profile 301 includes a high concentration of dopants having a shallow penetration depth. The deep profile 303 results from the contamination beam which has a relatively low concentration of neutralized ions impacting the substrate at a relatively high energy. Thus, deep profile 303 includes a lower dopant concentration and has a deeper penetration depth than the shallow dopant profile 301. The number of collisions experienced by the contamination ions is generally a function of the deceleration process. Therefore, aspects of the ion concentration of the contamination beam may be controlled by controlling a ratio between the first energy level (energy of ion beam 108) and the second energy level (energy of ion beam 114). This ratio is referred to herein as a deceleration ratio of the ion beams. For example, a deceleration of ions from a first energy level of 8 keV to a second energy level of 2 keV would have a deceleration ratio of 4. The dopant concentration and penetration depth of the deep profile 303 are a function of the deceleration ratio. In general, the greater the deceleration ratio, the greater then penetration depth of the deep profile 303. The smaller the deceleration ratio, the smaller the penetration depth of the deep profile 303. Thus, deceleration ratio may be used to select the characteristics of the deep profile 303. Dopant tail 305 represents a tail of a dopant profile formed using a deceleration ratio of 1. For such a deceleration ratio, no deceleration occurs in the ion beam 112. Therefore, the dopant profile 301 (and dopant tail 305) is a result of clean ion implantation.

In the exemplary dopant profile of FIG. 3, the clean dopant profile 301 is shallow and provides a region of low resistance that may be used, for example, to form a source and/or drain region on a semiconductor device. The contamination dopant profile extends to an interface 315 between semiconductor substrate 313 and a buried oxide layer 317. The contamination dopant profile may be used to provide a junction that extends into the buried oxide layer, as shown in FIG. 3. Thus, the methods disclosed herein may be used to achieve various device characteristics of the resulting ion implantation product.

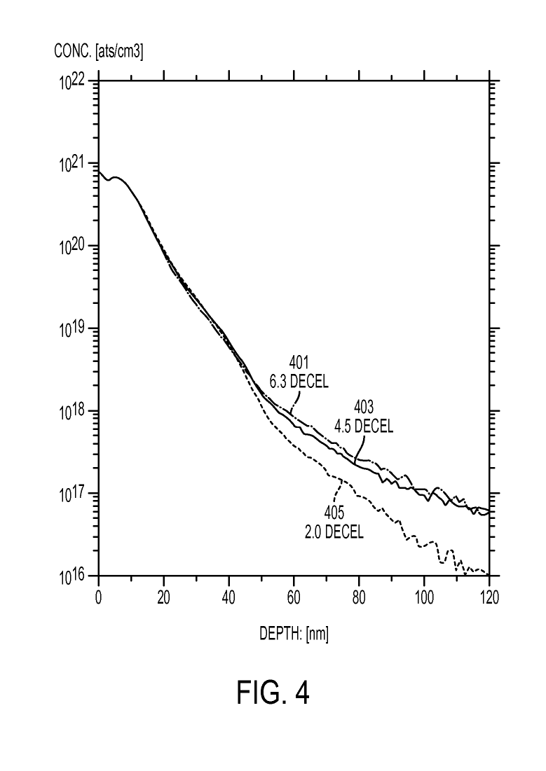

FIG. 4 shows various dopant profiles obtained using the methods disclosed herein. Profile 401 shows a dopant profile obtained using a deceleration ratio of 6.3. Profile 403 shows a dopant profile obtained using a deceleration ratio of 4.5. Profile 405 shows a dopant profile obtained using a deceleration ratio of 2.0. In the shallow region (less than a depth of about 45 nm), the profiles are approximately matched to each other. In the deep region (greater than a depth of about 45 nm), the dopant profiles diverge. The lower deceleration ratios produce less of an implant profile. For example, the dopant profile 405, corresponding to the lowest deceleration ratio, has the shallowest penetration depth and the lowest dopant concentration at those depths. Dopant profile 401, corresponding to the highest deceleration ratio, has the deepest penetration depth and the high dopant concentration at those depths.

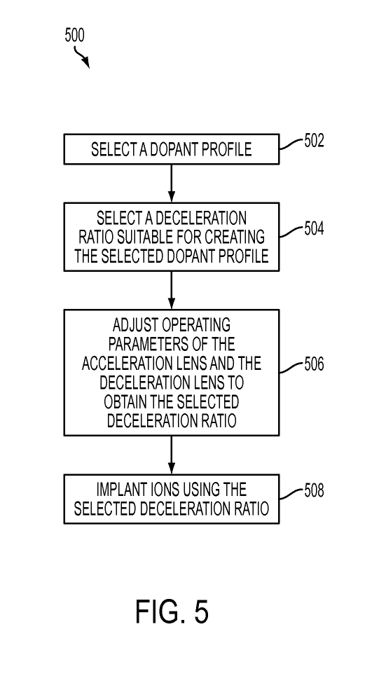

FIG. 5 shows a flowchart 500 illustrating an exemplary method of obtaining a selected dopant profile in a substrate. In box 502, a dopant profile is selected, for example, the contamination dopant profile (i.e., deep profile 303) or a combination of clean dopant profile (i.e., shallow profile 301) and contamination dopant profile 303. In box 504, a deceleration ratio is determined that contributes to formation of a contamination dopant profile, for example, a deceleration ratio that creates a selected contamination dopant profile. In box 506, an operational parameter of at least one of the acceleration electrode 106 and the deceleration electrode 112 are adjusted to obtain the selected deceleration ratio. In box 508, ions are implanted in the substrate using, for example, the exemplary apparatus 100 operating at the selected deceleration ratio. Clean ions form the selected shallow profile and contamination form the selected contamination profile.

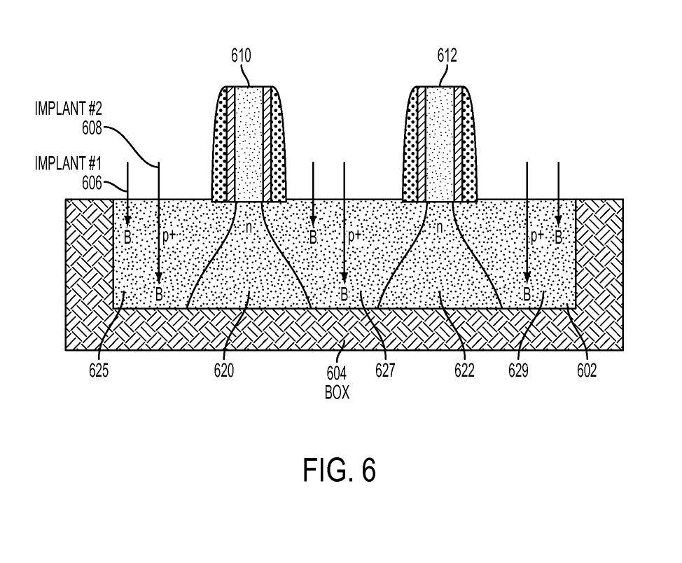

FIG. 6 shows an exemplary semiconductor device 600 formed using the methods disclosed herein. Substrate 602 is formed on a buried oxide layer 604 generally as a component of a semiconductor chip. In the exemplary illustration of FIG. 6, the substrate 602 is an n-type material with structures formed thereon. The structures are surface structure that may include exemplary gate structures 610 and 612 usable for semiconductor operations. In the exemplary embodiment, a clean ion beam 606 and a contamination ion beam 508 may be implanted in the substrate 602. In the illustrative embodiment, the dopant atoms are boron atoms. The clean beam of ions 606, when implanted, forms a shallow layer having a high concentration of dopant atoms. The contamination atoms 608 are implanted at a deep penetration depth within the substrate 602, thus providing a dopant profile that extends to the buried oxide layer 604. The deep dopant profile isolates n-type regions 620 and 622 from each other using p-doped regions 625, 627 and 629. Without the deep dopant profile, the n-type regions 620 and 622 connect and may provide undesired cross-talk. The deep dopant profile therefore reduces a possible cross-talk between n-type regions 620 and 622 in a single manufacturing step. In an additional process, the clean beam of ions may be decelerated from the second energy level to obtain a second contamination beam. The second contamination beam may then be implanted in the substrate to obtain a second dopant profiles, thus enabling the operator to obtain different dopant profiles.

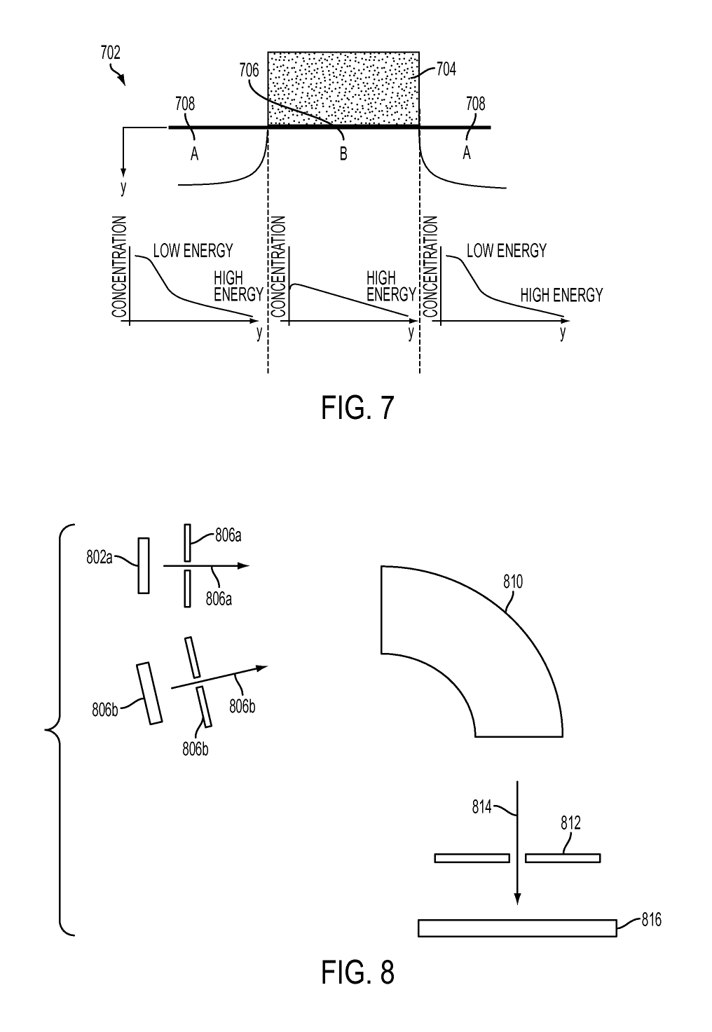

In another embodiment, an implantation profile may be defined and the profile may be achieved by controlling the deceleration ratio and using an existing structure. FIG. 7 shows an exemplary wafer substrate 702 having an existing structure 704 formed on its surface. The existing structure 704 may be used to achieve a selected ion implantation profile by blocking a low energy component of the ion beam (contamination beam) in the region B 706 and allowing both high (clean) and low (contamination) energy components of the ion beam to be implanted in the region A 708. If the blocking structure does not exist, the ion implantation profile may nonetheless be achieved via a single ion implantation step by using a blocking insulator.

In an additional embodiment, multiple ion species may be implanted in the wafer substrate using multiple decelerations ratios. FIG. 8 shows an exemplary ion implantation apparatus 800 suitable for performing the ion implantation of multiple ion species. The apparatus includes a first ion source 802a providing a first species of ions at a front end of the apparatus 800 and a second ion source 802b providing a second species of ions at the front end of the apparatus 800. Acceleration electrode 806a accelerates the first species of ions into a first beam 808a having a first selected energy level. Acceleration electrode 806b accelerates the second species of ions into a second beam 808b having a second energy level. First beam 808a and second beam 808b pass through beam line 810 and are decelerated at decelerating electrode 812 to beams 814 having lower energy levels for ion implantation at the substrate 816. Each of the acceleration electrodes 806a and 806b may be operated independently to provide separate control of the first energy level and the second energy level. The first energy level and the second energy level may be different energy levels and the decelerations ratios for the first beam 808a and the second beam 808b may be independently controlled. Therefore, the deceleration ratios may be independently controlled in order to control separate implantation profiles for each of the first species of ions and the second species of ions in a single implantation procedure.

The methods disclosed herein may be used to produce a selected dopant profile in a substrate using a single manufacturing process. This is in contrast to prior art methods of producing a dopant profile that deviates from the standard “clean” dopant profile. In prior art methods, contamination ions are removed from the ion beam prior to implantation at the substrate, producing only dopant profiles corresponding to the clean ions. In the prior art, in order to create a dopant profile that deviates from such the clean profile, one or more additional steps are used requiring different ion beam energies, using the clean atoms. The methods disclosed herein allows for producing the selected profile using a single step. Therefore, the present method uses the control of the contamination ions to achieve a selected dopant profile, thus reducing a number of manufacturing steps and extended queue times related to mass production. Various characteristics of the contamination dopant profile, such as dopant concentration and penetration depth can be controlled.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A method of ion implantation, comprising:
accelerating a beam of ions to a first energy level;
decelerating the beam of ions from the first energy level to produce a contamination beam of ions via an ion collision process; and
implanting ions of the contamination beam in a substrate to obtain a selected dopant profile in the substrate that extends to a buried oxide layer of the substrate to isolate an n-type region associated with a gate structure of a semiconductor device formed on the substrate.

2. The method of claim 1, wherein a characteristic of the selected dopant profile is related to a deceleration ratio of the first energy level and a second energy level, further comprising selecting the deceleration ratio to obtain the selected dopant profile having the characteristic.

3. The method of claim 2, wherein the characteristic is at least one of a penetration depth and an ion concentration of the selected dopant profile.

4. The method of claim 3, wherein selecting the deceleration ratio further comprises altering an operating parameter of at least one of a first electrode for accelerating the beam of ions to the first energy level and a second electrode for decelerating the beam of ions to the second energy level.

5. The method of claim 1, further comprising decelerating the beam of ions from the first energy level to a second energy level to obtain a clean beam of ions at the second energy level, and implanting the clean beam of ions and the contamination beam of ions in the substrate to obtain the selected dopant profile in the substrate.

6. The method of claim 1, further comprising decelerating the clean beam of ions from the second energy level to obtain a second contamination beam and implanting ions from the second contamination beam in the substrate.

7. The method of claim 1, further comprising blocking implantation of at least the contamination beam in a region of the substrate using a blocking element at the region of the substrate.

8. A method of obtaining an ion doping profile, comprising:
accelerating a first species of ions to a first energy level;
accelerating a second species of ions to a second energy level;
decelerating the first species of ions from the first energy level and the second species of ions from the second energy level to produce a first contamination beam containing the first species of ions and a second contamination beam containing the first species of ions; and
implanting at least the second contamination beam in a substrate to obtain a dopant profile that extends to a buried oxide layer of the substrate to isolate an n-type region associated with a gate structure of a semiconductor device formed on the substrate.

9. The method of claim 8, wherein a characteristic of the the first contamination beam is related to a first deceleration ratio of the first species of ions and a characteristic of the second contamination beam is related to a second deceleration ratio of the second species of ions, further comprising controlling at least one of the first deceleration ratio and the second deceleration ratio to control an ion dopant profile at the substrate.

10. The method of claim 9, further comprising independently controlling at least one of the first deceleration ratio and the second deceleration ratio during an ion implantation process.

11. The method of claim 9, wherein controlling at least one of the first and second deceleration ratios further comprises controlling at least one of an ion concentration and a penetration depth in of at least one of the first contamination beam and the second contamination beam.

12. The method of claim 9, wherein selecting the deceleration ratio for a selected ion species further comprises altering an operating parameter of at least one of an acceleration electrode for the selected ion species and a deceleration electrode.

13. A method of doping a substrate, comprising:
decelerating an ion beam from a first energy level to a second energy level to produce a contamination ion beam; and
directing the contamination ion beam onto the substrate to dope the substrate,
wherein a dopant profile of the contamination ion beam extends to a buried oxide layer of the substrate to form a p-doped region that isolates an n-type region associated with a gate structure of a semiconductor device formed on the substrate.

14. The method of claim 13, further comprising directing the contamination ion beam onto the substrate to obtain a dopant profile having a selected characteristic.

15. The method of claim 14, wherein the selected characteristic of the dopant profile is related to a deceleration ratio of the first energy level and the second energy level, further comprising selecting the deceleration ratio to obtain the dopant profile having the selected characteristic.

16. The method of claim 15, wherein the characteristic is at least one of an ion concentration and a penetration depth of the portion of the ion dopant profile.

17. The method of claim 15, wherein selecting the deceleration ratio further comprises altering an operating parameter of at least one of a first electrode for accelerating the beam of ions to the first energy level and a second electrode for decelerating the beam of ions to the second energy level.

18. The method of claim 13, wherein decelerating the beam of ions from the first energy level to the second energy level produces a clean beam of ions at a second energy level, further comprising implanting the clean beam of ions at the second energy level onto the substrate.

19. The method of claim 18, further comprising decelerating the clean beam of ions from the second energy level to obtain a second contamination beam and implanting ions from the second contamination beam in the substrate.

20. The method of claim 13, further comprising using a dopant profile resulting from the contamination beam to alter a property of a semiconductor material formed from the substrate.
